(19) United States
(12) Patent Application Publication
(10) Pub. No.: US 2025/0358991 A1
(43) Pub. Date: Nov. 20, 2025

(54) PREPARATION METHOD FOR A SELECTIVE ELECTROMAGNETIC SHIELDING AND AN ELECTRONIC PRODUCT

(71) Applicant: Universal Global Technology (Shanghai) Co., Ltd., Shanghai (CN)

(72) Inventors: Hongsong Yu, Shanghai (CN); Biao Hu, Shanghai (CN); Rencai Zhang, Shanghai (CN); Huiying Li, Shanghai (CN)

(73) Assignee: Universal Global Technology (Shanghai) Co., Ltd., Shanghai (CN)

(21) Appl. No.: 19/019,736

(22) Filed: Jan. 14, 2025

(30) Foreign Application Priority Data
May 14, 2024 (CN) 202410599526.X

(51) Int. Cl. H05K 9/00; H05K 1/02

(52) U.S. Cl. CPC H05K 9/0084; H05K 1/0227; H05K 9/0092; H05K 2201/0715

(57) ABSTRACT

The present application provides a preparation method for a selective electromagnetic shielding and an electronic product thereof, the method comprising: printing electromagnetic shielding ink on a first area on a surface of an electronic packaging module by pad printing, wherein the first area is an area requiring electromagnetic shielding; curing the electromagnetic shielding ink to form an electromagnetic shielding layer. Compared with the existing selective sputtering process, the present application reduces the use of auxiliary materials, reduces costs, has a simple and stable process, does not require vacuum conditions, and promotes low-carbon and environmentally friendly practices.

### FIELD OF THE DISCLOSURE

The present application relates to a technical field of semiconductor technology, and particularly to a preparation method for a selective electromagnetic shielding and an electronic product.

### BACKGROUND

With the rise of SIP (System in Package) technology, multiple chips are often concentrated in one package, but different chips have different requirements for electromagnetic shielding, so only part of the SIP module needs to be electromagnetically shielded, so selective shielding technology is introduced.

A common method to achieve selective shielding is the selective sputtering process. For example, before sputtering, the non-electromagnetic shielding area is masked with tape, and then sputtering and debonding are performed. This method has the following problems:
1. The process is lengthy and requires taping and debonding. There are potential process risks, such as burn mark (the board is easy to burn black), residual tape and overflow plating, incomplete debonding, and burr and other problems, which affect product quality.
2. A large number of auxiliary materials are required, such as carrier tape, mask tape and support tape, etc.
3. Use a lot of supporting auxiliary equipment, such as placement machines and detach equipment.
4. Sputter requires the cavity to be evacuated (<10⁻³ Torr) and other harsh environmental conditions.

Therefore, a simpler process is expected to achieve a selective electromagnetic shielding operation.

### SUMMARY OF THE INVENTION

One of the purposes of this application is to provide a preparation method for a selective electromagnetic shielding and an electronic product to solve at least part of the problems existing in the prior art.

The technical solution provided by the present application is as follows:

A preparation method for a selective electromagnetic shielding, comprising:
printing electromagnetic shielding ink on a first area on a surface of an electronic packaging module by pad printing, wherein the first area is an area requiring electromagnetic shielding; curing the electromagnetic shielding ink of the first area to form an electromagnetic shielding layer.

In some embodiments, the step of printing electromagnetic shielding ink on a first area on a surface of an electronic packaging module by pad printing comprises:
printing the electromagnetic shielding ink on the first area on the surface of the electronic packaging module by a first type of printing, and curing the electromagnetic shielding ink to obtain a first shielding layer;
printing the electromagnetic shielding ink on the edge area of the first area by a second type of printing, and curing the electromagnetic shielding ink to obtain a second shielding layer.

In some embodiments, before performing the first type of printing, further comprising:
manufacturing a first type of printing plate for the first type of printing, wherein the first type of printing plate comprises a groove that is consistent with a shape of the first area, and the groove is used to accommodate the electromagnetic shielding ink.

In some embodiments, manufacturing a second type of printing plate for the second type of printing, wherein the second type of printing plate comprises a groove that is consistent with a shape of the edge area of the first area, and the groove is used to accommodate the electromagnetic shielding ink.

In some embodiments, a printing depth of the first type of printing is greater than a printing depth of the second type of printing.

In some embodiments, printing the electromagnetic shielding ink on the first area on the surface of the electronic packaging module by performing the first type of printing multiple times.

In some embodiments, printing the electromagnetic shielding ink on the edge area of the first area by performing the second type of printing multiple times.

In some embodiments, the electromagnetic shielding ink is a silver glue.

In some embodiments, the first type of printing supports printing of multiple surfaces simultaneously.

The present application also provides an electronic product, the electronic product comprises an electronic packaging module, and the preparation method for a selective electromagnetic shielding according to any one of the above embodiments is used to perform a selective electromagnetic shielding operation on a surface of the electronic packaging module.

The preparation method for a selective electromagnetic shielding and an electronic product provided by the present application at least brings about the following beneficial effects: compared with the existing selective sputtering process, the present application reduces the use of auxiliary materials, reduces costs, has a simple and stable process, does not require vacuum conditions, and promotes low-carbon and environmentally friendly practices.

### BRIEF DESCRIPTION OF THE DRAWINGS

The preferred embodiments will be described below in a clear and understandable manner in conjunction with the accompanying drawings to further illustrate the above-mentioned characteristics, technical features, advantages and implementation methods of a preparation method for a selective electromagnetic shielding and an electronic product.

FIG. 1 is a flow chart of a preparation method for a selective electromagnetic shielding according to an embodiment of the present application;

FIG. 2 is a flow chart of a preparation method for a selective electromagnetic shielding according to another embodiment of the present application;

FIG. 3 is a three-dimensional schematic diagram of a product prepared in another embodiment of the present application;

FIG. 4 is a schematic diagram of a process for preparing a product in another embodiment of the present application;

FIG. 5 is a schematic diagram of a slice photo of the SIP module after the first type of printing;

FIG. 6 is a schematic diagram of a slice photo of the SIP module after the second type of printing;

FIG. 7 is a schematic top view of the printing plate.

FIG. 8 is a schematic diagram of the printing depth of pad printing.

### DESCRIPTION OF THE ILLUSTRATED EMBODIMENTS

To more clearly illustrate the embodiments of the present application or the technical solutions in the prior art, the specific implementation methods of the present application will be described below with reference to the accompanying drawings. Obviously, the accompanying drawings described below are only some embodiments of the present application. For ordinary technical persons in this field, other drawings and other implementation methods can be obtained based on these drawings without creative work.

To simplify the drawings, only the parts related to the present application are schematically shown in each figure, and they do not represent the actual structure of products. In addition, to simplify the drawings and facilitate understanding, in some figures, only one of the parts with a same structure or function is schematically drawn or marked. In this specification, “one” not only means “only one”, but also may mean “more than one”.

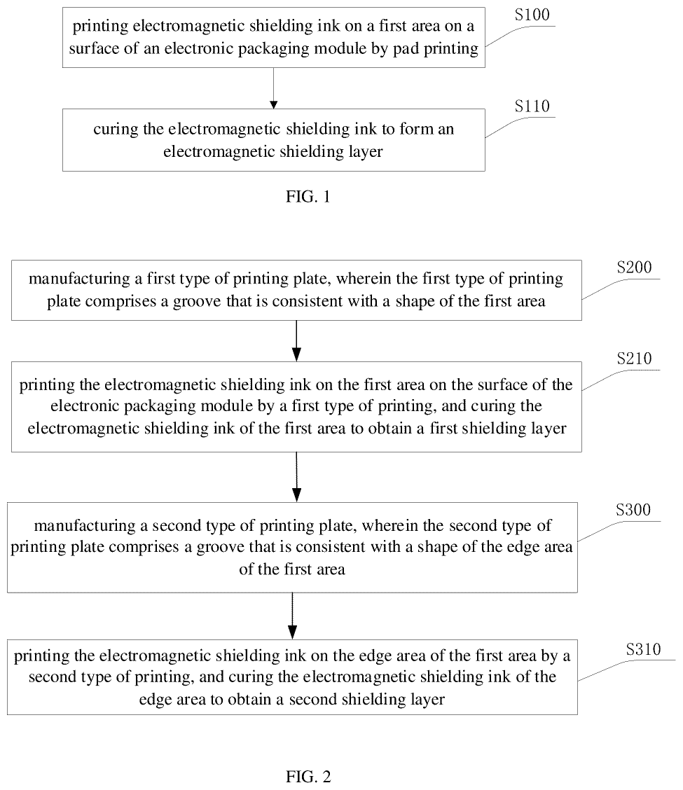

In one embodiment of the present application, as shown in FIG. 1, a preparation method for a selective electromagnetic shielding comprises:
Step S100: printing electromagnetic shielding ink on a first area on a surface of an electronic packaging module by pad printing;
Step S110: curing the electromagnetic shielding ink of the first area to form an electromagnetic shielding layer.

Specifically, the electronic packaging module may be an SIP packaging module, which may comprise a substrate and a packaging structure, wherein the packaging structure further comprises a plurality of electronic components disposed on the substrate and a plastic packaging body covering the electronic components.

The surface of the electronic packaging module is provided with a first area and a second area, the first area is an area requiring electromagnetic shielding, and the second area is an area not requiring electromagnetic shielding.

The first area may include one surface or multiple surfaces. For example, the top surface and four side surfaces of the module need to be electromagnetically shielded, or only the top surface needs to be electromagnetically shielded, or only a part of the top surface needs to be electromagnetically shielded.

Electromagnetic shielding ink is a special ink used to shield electromagnetic interference (EMI). Applying it on the surface of an object that needs electromagnetic shielding can prevent or reduce the interference and radiation of electromagnetic waves. It can be a substance composed of conductive particles and colloidal solution. The conductive particles can be selected from gold, silver, copper, and nickel. For example, electromagnetic shielding ink can be conductive silver glue.

Printing electromagnetic shielding ink on a first area on a surface of an electronic packaging module by pad printing.

Pad printing technology is a precision processing method that transfers a pattern from a special printing template (referred to as a printing plate, also known as an “intaglio”) to the surface of a product. It transfers the pattern information on the printing plate to the substrate through the action of a pad printing rubber head (using a soft elastic material, such as silicone). The main steps are as follows:

For example, grooves are created on the printing plate through etching or photolithography processes. Ink is applied to the grooves on the printing plate, and a suitable silicone rubber head is selected. The rubber head is pressed onto the groove pattern to pick up the pattern, then moved to the printing position. The rubber head is pressed onto the product surface, and a certain amount of pressure is applied to transfer the ink onto the product.

In this embodiment, electromagnetic shielding ink is selected to replace ordinary ink. The electromagnetic shielding ink in the printing plate is transferred to the first area on the surface of the electronic packaging module by pad printing. After printing is completed, the electronic packaging module is placed in an oven for baking to cure the ink layer in the first area, thereby forming an electromagnetic shielding layer.

According to the area to be printed, grooves of corresponding shapes are carved or etched on the printing plate. These grooves are used to accommodate the ink and transfer the ink to the substrate during the printing process to achieve the final printing effect. Metal materials such as stainless steel, chrome steel, etc. can be used to make the printing plate.

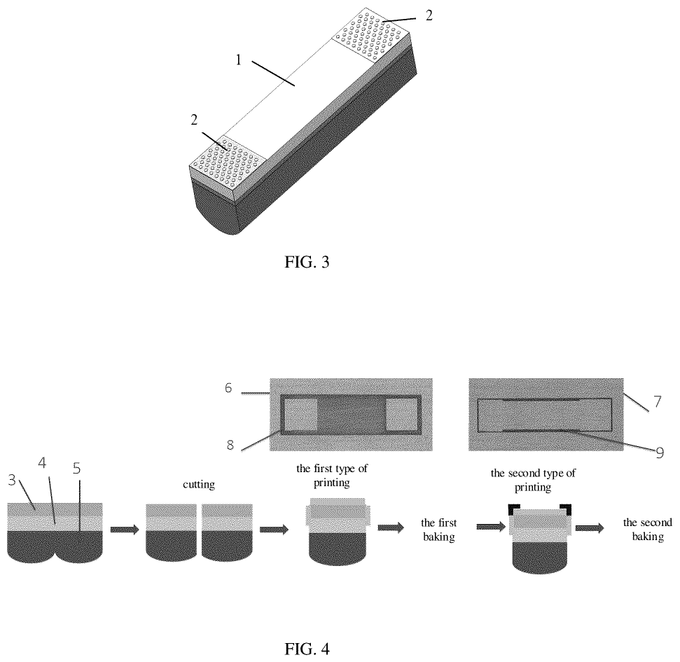

When the first area contains multiple surfaces, the printing of multiple surfaces can be completed by multiple pad printings, and the printing of one surface or part of the surface can be completed at one time; or the printing of all surfaces can be supported by one pad printing at the same time, which mainly depends on the design of the printing plate. Taking the selective shielding of the product shown in FIG. 3 as an example, if the first area 1 on the top surface of the product and the light gray areas on the four sides need electromagnetic shielding, and other parts do not need electromagnetic shielding, the printing plate shown in FIG. 7 (top view of the printing plate) can be designed, in which the dark black part (corresponding to the grooves filled with ink) constitutes the pattern of the printing plate, and this printing plate can be used to complete the printing of 5 surfaces at one time. It is also possible to design 3 types of printing plates, one for printing on the top surface, one for printing on the front and back sides, and one for printing on the left and right sides, and complete the printing of the entire shielding layer through 3 printings. Printing on multiple surfaces at one time can improve printing efficiency.

In this embodiment, an electromagnetic shielding layer is formed on the surface of the electronic packaging module by pad printing. Multi-sided selective shielding can be achieved by adjusting the printing plate. Compared with the existing selective sputtering process, the present application reduces the use of auxiliary materials, reduces costs, has a simple and stable process, does not require vacuum conditions, and promotes low-carbon and environmentally friendly practices.

In another embodiment of the present application, as shown in FIG. 2, a preparation method for a selective electromagnetic shielding comprises:
Step S200: manufacturing a first type of printing plate, wherein the first type of printing plate comprises a groove that is consistent with a shape of the first area, and the groove is used to accommodate the electromagnetic shielding ink;
Step S210: printing the electromagnetic shielding ink on the first area on the surface of the electronic packaging module by a first type of printing, and curing the electromagnetic shielding ink of the first area to obtain a first shielding layer.
Step S300: manufacturing a second type of printing plate, wherein the second type of printing plate comprises a groove that is consistent with a shape of the edge area of the first area, and the groove is used to accommodate the electromagnetic shielding ink;
Step S310: printing the electromagnetic shielding ink on the edge area of the first area by a second type of printing, and curing the electromagnetic shielding ink of the edge areas to obtain a second shielding layer.

Specifically, the surface of the electronic packaging module is provided with a first area and a second area, the first area is an area requiring electromagnetic shielding, and the second area is an area not requiring electromagnetic shielding. Electromagnetic shielding ink is a special ink used to shield electromagnetic interference.

The first type of printing refers to printing electromagnetic shielding ink on the first area of the surface of the electronic packaging module by pad printing. The second type of printing refers to printing electromagnetic shielding ink on the edge area of the first area of the surface of the electronic packaging module by pad printing.

The edge area refers to the boundary between two or more planes on the surface of an object. It represents the discontinuity or edge of the surface structure and has specific geometric characteristics.

Since the pad printing rubber head has a greater pressure on the edge of the electronic packaging module, less ink or even no ink is printed on the edge of the electronic packaging module, making it impossible to form a complete electronic shielding layer, thus affecting the electromagnetic shielding effect of the product. Therefore, it is necessary to use the second type of printing to reprint the edge area to increase the ink thickness in the edge area.

The first type of printing plate is used for the first type of printing, and the second type of printing plate is used for the second type of printing. The second type of printing is only for the edge area, so when manufacturing the second type of printing plate, the grooves need to be set in the edge areas only.

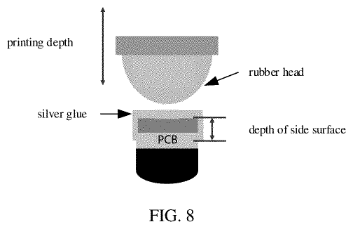

The first type of printing needs to complete a larger area of printing, while the second type of printing only needs to complete the printing of the edge area. When performing the first type of printing, high pressure is required and the printing depth is deep; when performing the second type of printing, low pressure is required and the printing depth is shallow to ensure that the edge areas are evenly covered by ink. The printing depth is shown in FIG. 8.

The first type of printing and the second type of printing are each performed at least once, and the first shielding layer and the second shielding layer can be obtained by the two types of printing. The first shielding layer and the second shielding layer constitute an electromagnetic shielding layer with better coverage.

In this embodiment, the first type of printing is performed first, and the electromagnetic shielding ink of the first type of printing is cured before the second type of printing is performed. In actual operation, the second type of printing can also be performed first, and the electromagnetic shielding ink of the second type of printing is cured before the first type of printing is performed. This application does not make any limitation on this.

In one embodiment, printing the electromagnetic shielding ink on the first area on the surface of the electronic packaging module by performing the first type of printing multiple times to increase the ink thickness in the first area.

In one embodiment, printing the electromagnetic shielding ink on the edge area of the first area by performing the second type of printing multiple times to increase the ink thickness in the edge areas of the first area and ensure that the edge areas are evenly covered by ink.

In this embodiment, by adjusting the printing plate, the second type of printing is performed on the basis of the first type of printing, thereby increasing the thickness of the ink in the edge areas of the module; and by printing multiple times, the ink thickness of the entire first area is increased, thereby further improving the electromagnetic shielding performance of the module.

The present application also provides an embodiment, in which the aforementioned preparation method for a selective electromagnetic shielding is used to prepare the product shown in FIG. 3.

FIG. 3 is a three-dimensional schematic diagram of the product. On the top surface of the product, the first area 1 requires electromagnetic shielding, while the second area 2 does not require electromagnetic shielding. On the four sides of the product, the light gray part requires electromagnetic shielding and belongs to the first area (not shown), while the dark gray part does not require electromagnetic shielding and belongs to the second area (not shown).

The steps for product preparation are as follows (see FIG. 4):
Step 1: Pre-installing electronic components on a printed circuit board (PCB) 4 and performing double-sided plastic packaging using an injection molding process to obtain a plastic packaging body 3 and a plastic packaging body 5.
Step 2: Cutting the plastic-packaged PCB into individual SIP modules using Saw or laser cutting technology.
Step 3: Printing the pattern on the first type of printing plate 6 (the dark black part, which is composed of the groove 8 filled with conductive silver glue on the printing plate 6) onto the five surfaces of the SIP module (the area requiring electromagnetic shielding, i.e., the first area) using pad printing equipment, with the thickness of the conductive silver glue adjustable by adjusting the number of printing times.

Step 4: Baking in an oven at 150° C. for one hour to cure the first layer of conductive silver glue after the first type of printing is completed.

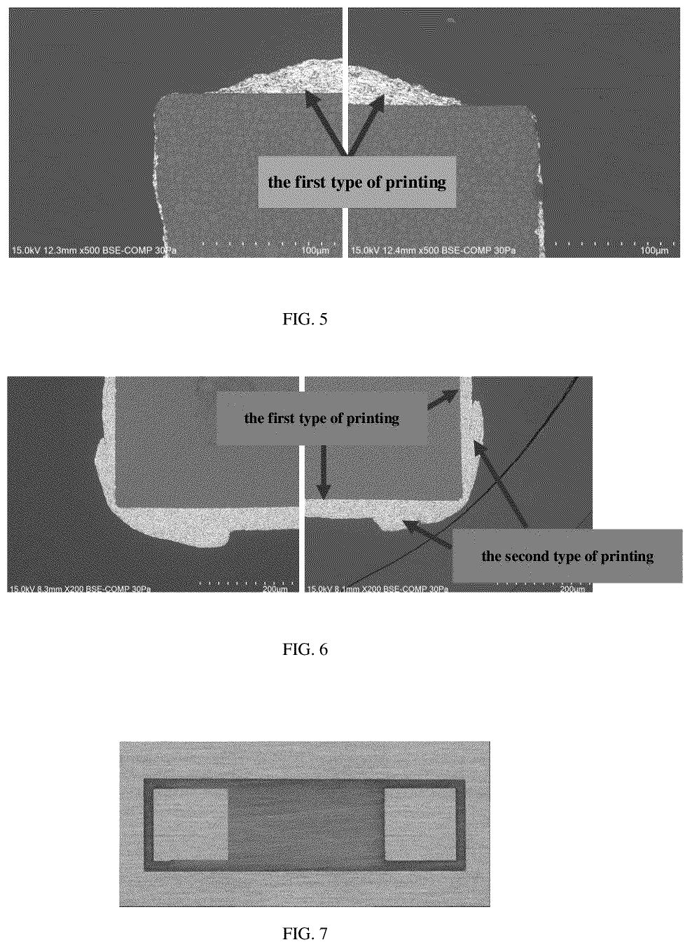

At this time, as shown in FIG. 5 (a slice photo of the module), it can be seen that the edges are covered with little or even no conductive silver glue.

Step 5: Printing the pattern on the second type of printing plate 7 (the dark black part, composed of the groove 9 filled with conductive silver glue on the printing plate 7) to the edge area of the SIP through a pad printing equipment, with the thickness of the conductive silver glue adjustable by adjusting the number of printing times.

Step 6: Baking in an oven at 150° C. for one hour to cure the second layer of conductive silver glue after the second type of printing is completed.

At this time, as shown in FIG. 6 (a slice photo of the module), it can be seen that through the second type of printing, the thickness of the silver glue at the edges is perfectly improved.

The first type of printing uses high pressure and deep printing depth to ensure that the conductive silver glue is connected to the PCB copper layer; the second type of printing uses low pressure and shallow printing depth to ensure that the edges of the SIP are evenly covered by the conductive silver glue.

This embodiment uses a pad printing process to perform selective electromagnetic shielding processing. By adjusting the printing plate, the second type of printing is performed on the basis of the first type of printing, thereby increasing the thickness of the conductive silver glue in the corner area of the module and further improving the electromagnetic shielding performance of the module.

In one embodiment of the present application, an electronic product comprises an electronic packaging module, and a selective electromagnetic shielding operation is performed on the surface of the electronic packaging module using the preparation method for a selective electromagnetic shielding described in any of the above embodiments.

It should be noted that the above embodiments can be freely combined as needed. The above are only preferred embodiments of the present application. It should be pointed out, that for ordinary skilled in the art, several improvements and modifications can be made without departing from the principle of the present application, and these improvements and modifications should also be regarded as within the protection scope of the present application.

1. A preparation method for a selective electromagnetic shielding, characterized by comprising:
printing electromagnetic shielding ink on a first area on a surface of an electronic packaging module by pad printing, wherein the first area is an area requiring electromagnetic shielding;
curing the electromagnetic shielding ink to form an electromagnetic shielding layer.

2. The preparation method according to claim 1, characterized in that the step of printing electromagnetic shielding ink on a first area on a surface of an electronic packaging module by pad printing comprises:
printing the electromagnetic shielding ink on the first area on the surface of the electronic packaging module by a first type of printing, and curing the electromagnetic shielding ink to obtain a first shielding layer;
printing the electromagnetic shielding ink on an edge area of the first area by a second type of printing, and curing the electromagnetic shielding ink to obtain a second shielding layer.

3. The preparation method according to claim 2, characterized in that, before performing the first type of printing, further comprising:
manufacturing a first type of printing plate for the first type of printing, wherein the first type of printing plate comprises a groove that is consistent with a shape of the first area, and the groove is used to accommodate the electromagnetic shielding ink.

4. The preparation method according to claim 2, characterized in that, before performing the second type of printing, further comprising:
manufacturing a second type of printing plate for the second type of printing, wherein the second type of printing plate comprises a groove that is consistent with a shape of the edge area of the first area, and the groove is used to accommodate the electromagnetic shielding ink.

5. The preparation method according to claim 2, characterized in that:
a printing depth of the first type of printing is greater than a printing depth of the second type of printing.

6. The preparation method according to claim 2, characterized in that:
printing the electromagnetic shielding ink on the first area on the surface of the electronic packaging module by performing the first type of printing multiple times.

7. The preparation method according to claim 2, characterized in that:
printing the electromagnetic shielding ink on the edge area of the first area by performing the second type of printing multiple times.

8. The preparation method according to claim 1, characterized in that:
the electromagnetic shielding ink is a silver glue.

9. The preparation method according to claim 2, characterized in that:
the first type of printing supports printing of multiple surfaces simultaneously.

10. An electronic product, characterized by comprising:
an electronic packaging module, wherein a first area on a surface of an electronic packaging module is printed with electromagnetic shielding ink by pad printing, and the first area is an area requiring electromagnetic shielding;
the electromagnetic shielding ink is cured to form an electromagnetic shielding layer.

11. The electronic product according to claim 10, characterized in that,
the first area on the surface of the electronic packaging module is printed with the electromagnetic shielding ink by a first type of printing, and the electromagnetic shielding ink is cured to obtain a first shielding layer;
the edge area of the first area is printed with the electromagnetic shielding ink by a second type of printing, and the electromagnetic shielding ink is cured to obtain a second shielding layer.

12. The electronic product according to claim 11, characterized in that, before performing the first type of printing, further comprising:
manufacturing a first type of printing plate for the first type of printing, wherein the first type of printing plate comprises a groove that is consistent with a shape of the first area, and the groove is used to accommodate the electromagnetic shielding ink.

13. The electronic product according to claim 11, characterized in that, before performing the second type of printing, further comprising:
manufacturing a second type of printing plate for the second type of printing, wherein the second type of printing plate comprises a groove that is consistent with a shape of the edge area of the first area, and the groove is used to accommodate the electromagnetic shielding ink.

14. The electronic product according to claim 11, characterized in that:
a printing depth of the first type of printing is greater than a printing depth of the second type of printing.

15. The electronic product according to claim 11, characterized in that:
printing the electromagnetic shielding ink on the first area on the surface of the electronic packaging module by performing the first type of printing multiple times.

16. The electronic product according to claim 11, characterized in that:
printing the electromagnetic shielding ink on the edge area of the first area by performing the second type of printing multiple times.

17. The electronic product according to claim 10, characterized in that:
the electromagnetic shielding ink is a silver glue.

18. The electronic product according to claim 11, characterized in that:
the first type of printing supports printing of multiple surfaces simultaneously.

19. The electronic product according to claim 11, characterized in that:
the second type of printing is performed on the basis of the first type of printing.

20. The preparation method according to claim 2, characterized in that:
the second type of printing is performed on the basis of the first type of printing.
